(19) United States
(12) Patent Application Publication
(10) Pub. No.: US 2014/0201599 A1
(43) Pub. Date: Jul. 17, 2014

(54) ERROR PROTECTION FOR INTEGRATED CIRCUITS IN AN INSENSITIVE DIRECTION

(71) Applicant: INTERNATIONAL BUSINESS MACHINES CORPORATION, Armonk, NY (US)

(72) Inventors: Kevin W. Kark, Poughkeepsie, NY (US); John G. Massey, Jericho, VT (US); K. Paul Muller, Wappingers Falls, NY (US); David L. Rude, Wendell, NC (US)

(73) Assignee: INTERNATIONAL BUSINESS MACHINES CORPORATION, Armonk, NY (US)

(21) Appl. No.: 13/741,603

(22) Filed: Jan. 15, 2013

(51) Int. Cl. H03M 13/05

(52) U.S. Cl. CPC H03M 13/05
USPC 714/773

(57) ABSTRACT

A method for providing error detection, or error detection combined with error correction, to an array of storage cells includes determining a sensitive direction and an insensitive direction of the storage cells and adding an error control mechanism to the array of storage cells in the insensitive direction. The insensitive direction is a direction perpendicular to a width of a gate conductor of the storage cells.

### CROSS REFERENCE TO RELATED APPLICATIONS

This application is related to the following U.S. Patent Applications which were filed concurrently herewith, each of which is hereby incorporated by reference: U.S. patent application Ser. No. ______ entitled ERROR PROTECTION FOR A DATA BUS; U.S. patent application Ser. No. ______ entitled PLACEMENT OF STORAGE CELLS ON AN INTEGRATED CIRCUIT; U.S. patent application Ser. No. ______ entitled ERROR PROTECTION FOR INTEGRATED CIRCUITS; and U.S. patent application Ser. No. ______ entitled SHARED ERROR PROTECTION FOR REGISTER BANKS.

### BACKGROUND

The present invention relates to integrated circuits, and more specifically, to error protection in integrated circuits having a sensitive and insensitive direction.

As integrated circuits continue to be made smaller, dependability is becoming increasingly important. For example, it has long been known that bit-flip errors in integrated circuits can be caused by alpha particles. However, as the size of integrated circuits becomes smaller, radiation-induced faults, such as single-event upsets (SEUs) and multi-bit upsets (MBUs), are becoming more common. An SEU or MBU can occur when a radiation particle passes through an integrated circuit. Upon impacting an integrated circuit, the particle may convert its kinetic energy to electrical energy which can be deposited in the circuitry. This energy can affect the state of the circuitry, for example flipping a bit, if the deposited energy exceeds the energy level which is required to hold the correct state. An SEU occurs when a particle changes the state of a single circuit element and an MBU occurs when a particle changes the state of two or more circuit elements. It is well known that cosmic rays and other common radiation types can result in SEUs and MBUs in integrated circuits. Indeed, as integrated circuits continue to decrease in size, lower energies are needed to change the internal state of the circuitry. Therefore, radiation-induced faults are becoming a reliability concern for modern integrated circuits.

Currently, faults in integrated circuits, such as MBUs, can be detected and/or corrected through the use of advanced error control techniques. However, such advanced error correction techniques require substantial overhead and are accordingly undesirable.

### SUMMARY

According to an exemplary embodiment, a method for providing error detection, or error detection combined with error correction, to an array of storage cells includes determining a sensitive direction and an insensitive direction of the storage cells and adding an error control mechanism to the array of storage cells in the insensitive direction. The insensitive direction is a direction perpendicular to a width of a gate conductor of the storage cells.

According to another exemplary embodiment, a method for configuring an array of storage cells includes determining a sensitive direction and an insensitive direction of the storage cells and selecting a location for the storage cells such that there is a minimum distance between adjacent storage cells in the insensitive direction. The method also includes adding an error control mechanism to the array of storage cells in the insensitive direction. The insensitive direction is a direction perpendicular to a width of a gate conductor of the storage cells.

According to another exemplary embodiment, a computer system for configuring an array of storage cells, the computer system comprising a processor, the computer system configured to perform a method. The method includes determining a sensitive direction and an insensitive direction of the storage cells and selecting a location for the storage cells such that there is a minimum distance between adjacent storage cells in the insensitive direction. The method also includes adding an error control mechanism to the array of storage cells in the insensitive direction. The insensitive direction is a direction perpendicular to a width of a gate conductor of the storage cells.

According to yet another exemplary embodiment, an integrated circuit includes an array of storage cells, wherein each of the storage cells includes a sensitive direction and an insensitive direction of the storage cells and an error control mechanism operable for detecting errors in the array of storage cells in the insensitive direction. The insensitive direction is a direction perpendicular to a width of a gate conductor of the storage cells.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a block diagram illustrating one example of a processing system for practice of the teachings herein;

FIG. 2 is a block diagram illustrating an exemplary six-transistor SRAM cell in accordance with the disclosure;

FIG. 3 is a schematic illustrating a two dimensional array of storage cells in accordance with the disclosure;

FIG. 4 is a schematic illustrating a two dimensional array of storage cells with multi-bit upsets in accordance with the disclosure;

FIG. 5 is a flow diagram that illustrates a method for providing error detection and/or correction for an array of storage cells in accordance with an exemplary embodiment;

FIG. 6 is a schematic illustrating a two dimensional array of storage cells in accordance with the disclosure; and

FIG. 7 is a flow diagram that illustrates a method for configuring error detection and/or correction for an array of storage cells in accordance with an exemplary embodiment.

### DETAILED DESCRIPTION

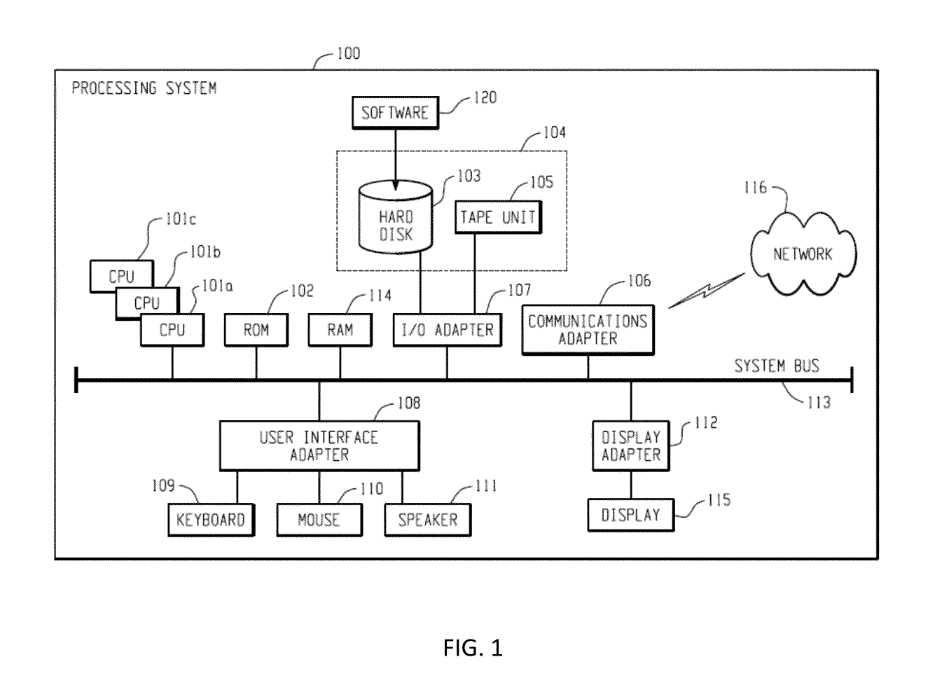

Referring to FIG. 1, there is shown an embodiment of a processing system 100 for implementing the teachings herein. In this embodiment, the system 100 has one or more central processing units (processors) 101a, 101b, 101c, etc. (collectively or generically referred to as processor(s) 101). In one embodiment, each processor 101 may include a reduced instruction set computer (RISC) microprocessor. Processors 101 are coupled to system memory 114 and various other components via a system bus 113. Read only memory (ROM) 102 is coupled to the system bus 113 and may include a basic input/output system (BIOS), which controls certain basic functions of system 100.

FIG. 1 further depicts an input/output (I/O) adapter 107 and a network adapter 106 coupled to the system bus 113. I/O adapter 107 may be a small computer system interface (SCSI) adapter that communicates with a hard disk 103 and/or tape storage drive 105 or any other similar component. I/O adapter 107, a direct access storage device or hard disk 103, and tape storage device 105 are collectively referred to herein as mass storage 104. A network adapter 106 interconnects bus 113 with an outside network 116 enabling data processing system 100 to communicate with other such systems and external storage devices. A screen (e.g., a display monitor) 115 is connected to system bus 113 by display adaptor 112, which may include a graphics adapter to improve the performance of graphics intensive applications and a video controller. In one embodiment, adapters 107, 106, and 112 may be connected to one or more I/O busses that are connected to system bus 113 via an intermediate bus bridge (not shown). Suitable I/O buses for connecting peripheral devices such as hard disk controllers, network adapters, and graphics adapters typically include common protocols, such as the Peripheral Components Interface (PCI). Additional input/output devices are shown as connected to system bus 113 via user interface adapter 108 and display adapter 112. A keyboard 109, mouse 110, and speaker 111 all interconnected to bus 113 via user interface adapter 108, which may include, for example, a Super I/O chip integrating multiple device adapters into a single integrated circuit.

Thus, as configured in FIG. 1, the system 100 includes processing capability in the form of processors 101, storage capability including system memory 114 and mass storage 104, input means such as keyboard 109 and mouse 110, and output capability including speaker 111 and display 115. In one embodiment, a portion of system memory 114 and mass storage 104 collectively store an operating system such as the z/OS® operating system from IBM Corporation to coordinate the functions of the various components shown in FIG. 1.

Examples of operating systems that may be supported by the system 100 include Windows 95, Windows 98, Windows NT 4.0, Windows XP, Windows 2000, Windows CE, Windows Vista, Macintosh, Java, LINUX, and UNIX, z/OS or any other suitable operating system. The system 100 also includes a network interface 116 for communicating over a network. The network can be a local-area network (LAN), a metro-area network (MAN), or wide-area network (WAN), such as the Internet or World Wide Web. Users of the system 100 can connect to the network through any suitable network interface 116 connection, such as standard telephone lines, digital subscriber line, LAN or WAN links (e.g., T1, T3), broadband connections (Frame Relay, ATM), and wireless connections (e.g., 802.11a, 802.11b, 802.11g).

As disclosed herein, the system 100 includes machine readable instructions stored on machine readable media (for example, the hard disk 104) for capture and interactive display of information shown on the screen 115 of a user. As discussed herein, the instructions are referred to as “software” 120. The software 120 may be produced using software development tools as are known in the art. Also discussed herein, the software 120 may also referred to as a “command line testing tool” 120, as a “testing interface” 120 or by other similar terms. The software 120 may include various tools and features for providing user interaction capabilities as are known in the art. The software 120 can include a database management subsystem such as DB2®, which manages structured data access requests and queries from end users and applications.

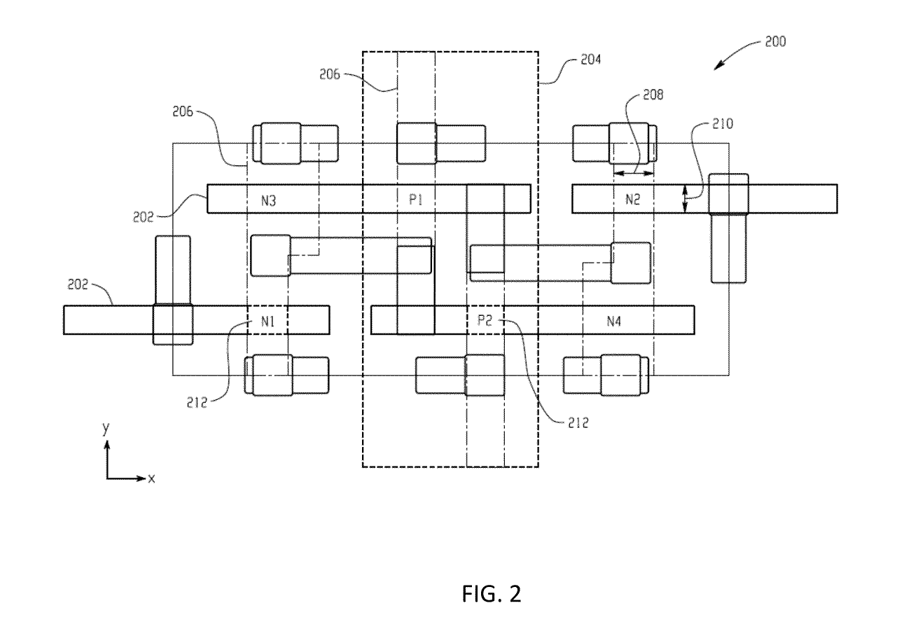

Referring now to FIG. 2, a schematic illustrating an exemplary six-transistor SRAM cell 200 in accordance with the disclosure is shown. The SRAM cell includes a plurality of gate conductors 202, an n-well region 204 and multiple active regions 206. Active regions 206 that fall within the n-well region 204 are, by definition, p-type devices (PFETs) while active regions 206 that fall outside of the n-well region 204 are n-type devices (NFETs.) The intersection of a gate conductor 202 and an active region 206 defines the transistor of the SRAM cell as shown, for example, by the boxes 212 for an NFET (N1) and a PFET (P2). The gate conductors 202 are configured in such a way as to have a transistor device length 208 in the x-direction and a transistor device width 210 in the direction of the y-axis. As illustrated, the gate conductors 202 of the SRAM cell 200 are configured such that they are substantially parallel to one another in the x-direction. It will be appreciated by those of ordinary skill in the art that the configuration of the SRAM cell 200 illustrated is one of several possible configurations and that the configuration illustrated is not intended to be limiting in anyway.

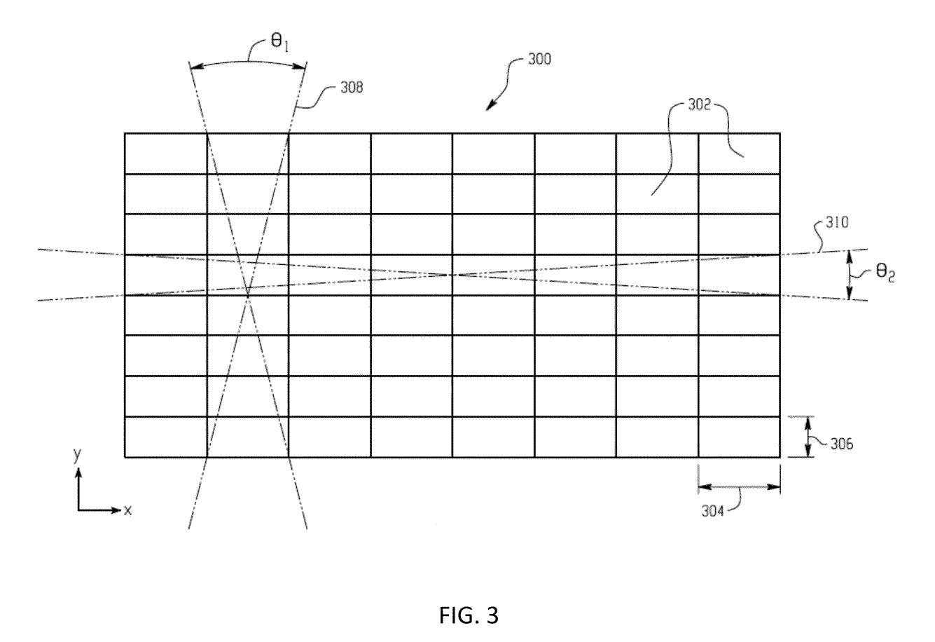

Referring now to FIG. 3 is a schematic illustrating a two dimensional array 300 of storage cells 302, such as the SRAM cell depicted in FIG. 2. In exemplary embodiments, the storage cells 302 may be SRAM cells, latches, register file cells, content-addressable memory cells, flip-flops, DRAM, e-DRAM, or any other storage cell. It will be appreciated by those of ordinary skill in the art that the configuration of the storage cells 302 in the array 300 illustrated is one of several possible configurations and that the configuration illustrated is not intended to be limiting in any way.

During operation of the array 300 of storage cells 302 a particle, or particle beam 308, 310, can impact two or more storage cells 302 thereby causing a multi-bit upset (“MBU”). Due to the dimensions of the gates of storage cells 302, particularly the difference in the length 304 and width 306 of the gates, a particle, or particle beam 308, traveling generally in the y-direction has a much higher likelihood of impacting a plurality of storage cells 302 and causing an MBU as compared to a particle, or particle beam 310, traveling generally in the x-direction. In exemplary embodiments, the range of the angles that a particle or particle beam 308 can strike the storage cells gates in the array 300 in the y-direction and cause an MBU can be represented by Θ₁ and the range of the angles that a particle or particle beam 310 can strike the storage cells gates in the array 300 in the x-direction and cause an MBU can be represented by Θ₂. In exemplary embodiments, when the length 304 of the gates of the storage cells 302 is greater than the width 306 of the gates of the storage cells 302, Θ₁ will be greater than Θ₂. In addition, the probability that a particle will cause an MBU in a given direction, for example the y-direction, is proportional to the range of the angles, for example Θ₁. The different probabilities of MBUs in each direction may be further compounded by the difference in length and width of the gate conductors, which may have length-width ratios larger than 10.

Since the likelihood of experiencing an MBU due to a particle beam in the y-direction is higher than in the x-direction, the y-direction is referred as a sensitive direction of the array 300 and the x-direction is referred to as an insensitive direction of the array 300. In exemplary embodiments, the sensitive direction of the array 300 of storage cells 302 can be defined as being perpendicular to the length 304 of storage cell gates and the insensitive direction of the array 300 of storage cells 302 can be defined as being perpendicular to the width 306 of the storage cell gates. In exemplary embodiments, the sensitive direction of the array 300 of storage cells can be defined as being perpendicular to the length 208 of the gate conductor 202 and the insensitive direction of the array 300 of storage cells 302 can be defined as being perpendicular to the width 210 of the gate conductor 202.

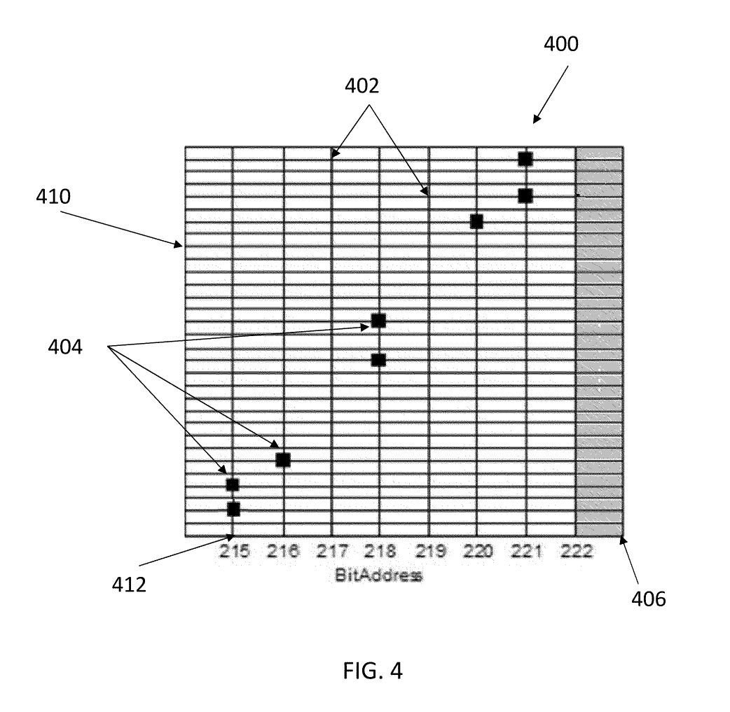

Referring now to FIG. 4, a memory array 400 is shown with word lines 410 running horizontally and bit lines 412 running vertically. The array 400 includes a plurality of storage cells 402 that are located at the intersections of the word lines 410 and bit lines 412. As illustrated, the array 400 includes a plurality of storage cells 404 which have experienced an error or bit flip caused by a particle, such as a proton. Based on the configuration of the storage cells 402 in the array 400, the word lines 410 are determined to be disposed in the insensitive direction and the bit lines 412 are disposed in the sensitive direction. Once the sensitive and insensitive directions of the array 400 of storage cells are determined, an error control mechanism 406 is added to the array 400 such that the error control mechanism 406 is configured to detect errors that occur in the insensitive direction, in this case in the word line 410.

In exemplary embodiments depending upon the application and the level of error detection and/or protection desired the error control mechanism 406 may include a parity protection bit, an error control coding (“ECC”), or another form of error detection and correction. In general, parity protection provides single-bit error detection, but it does not handle even numbers of multi-bit errors, and provides no way to correct detected errors. Advanced error detection and correction protocols, such as single-error correction double-error detection codes, are capable of detecting both single-bit and multi-bit errors and correcting single-bit errors. These protocols use a special algorithm to encode information in a block of bits that contains sufficient detail to permit the recovery of one or more bit errors in the data. Unlike parity protection, which uses a single bit to provide protection to some number of bits, ECC circuits may use larger groupings such as 7 bits to protect 32 bits, or 8 bits to protect 64 bits. In general, the strength of an error control mechanism is represented by the Hamming distance of the error control mechanism, which indicates the minimum number of binary digits that differ between any two code words in the code.

As shown in FIG. 4, the error control mechanism 406 is added to the word lines 410 of the array 400. In one embodiment, the error control mechanism 406 may be a single bit parity protection configured to detect errors that occur in the insensitive direction. For example, the single bit parity protection will be able to detect each of the illustrated the single bit upsets in storage cells 404. Furthermore, if the error control mechanism 406 is an ECC, the ECC will be able to detect and correct each of the single bit upsets in storage cells 404.

In contrast, if the error control mechanism 406 was added to the bit lines 412, which are in the sensitive direction, the error control mechanism 406 would be significantly less effective at detecting the upsets shown in the storage cells 404. For example, in the array shown in FIG. 4, if the error control mechanism 406 was a parity protection bit added to the bit lines 412, the error control mechanism 406 would not be capable of detecting the multi-bit upsets illustrated on bit lines 215, 218 and 221. Accordingly, by placing the error control mechanism 406 in the insensitive direction, the effectiveness of the error control mechanism 406 is increased and the overhead associated with the error control mechanism 406 can be decreased.

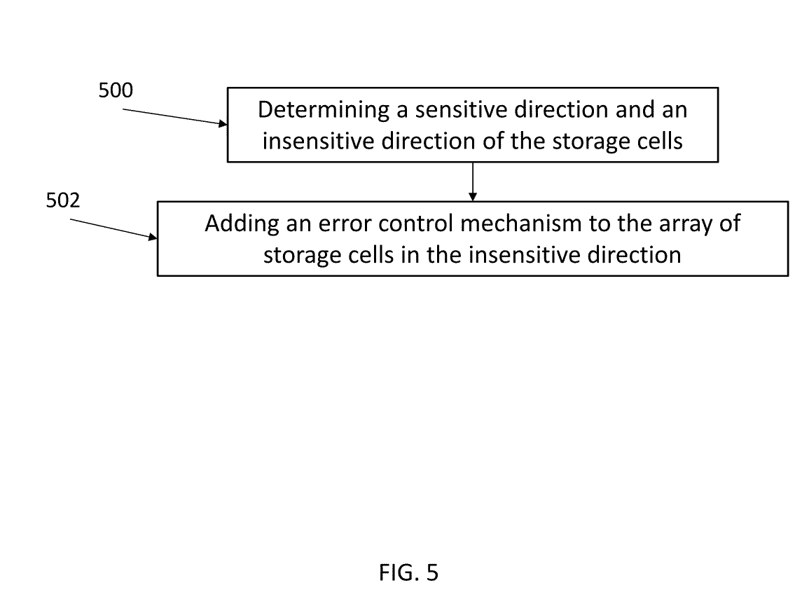

Referring now to FIG. 5, a flow diagram that illustrates a method for providing error detection for an array of storage cells in accordance with an exemplary embodiment is shown. As illustrated at block 500, the method includes determining a sensitive direction and an insensitive direction of the storage cells. In one embodiment, the insensitive direction is determined to be a direction perpendicular to a width of a gate conductor of the storage cells. In another embodiment, the insensitive direction is determined to be a direction perpendicular to a width of the storage cells. As shown at block 502, the method includes adding an error control mechanism to the array of storage cells such that the error control mechanism is configured to detect errors that occur in the insensitive direction. In exemplary embodiments, the error control mechanism may be a parity protection bit or an ECC.

In general, the probability of experiencing MBUs in a direction decreases as the distance between the storage cells in that direction is increased. Accordingly, by increasing the distance between the storage cells in the insensitive or sensitive direction the number of MBUs that are experienced by the array of storage cells can be decreased. In exemplary embodiments, the distance between storage cells of an array can be controlled to ensure that the probability of experiencing MBUs in a given direction fall below an acceptable threshold.

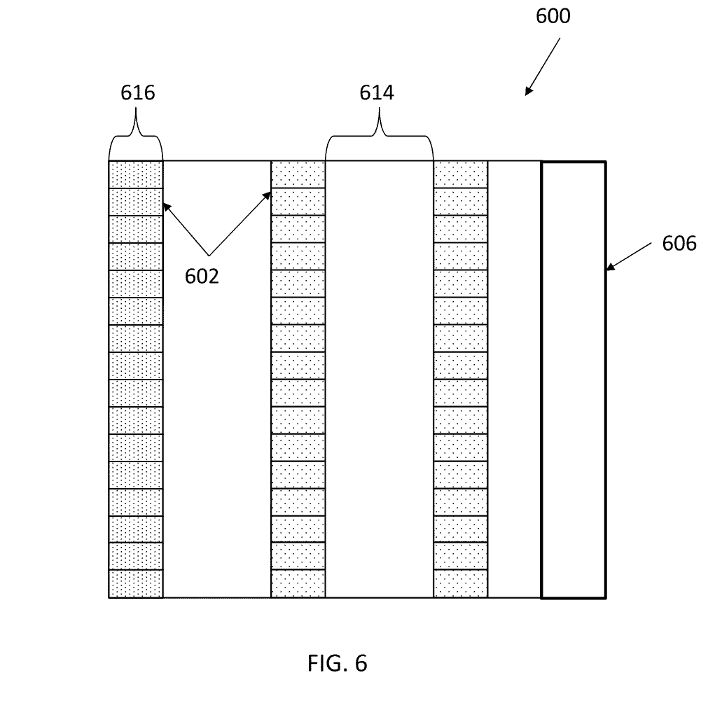

Referring now to FIG. 6, a schematic illustrating a two dimensional array 600 of storage cells 602 in accordance with the disclosure is shown. As illustrated, the storage cells 602 of the array 600 are disposed such that a distance 614 between adjacent storage cells 602 has a minimum value. In exemplary embodiments, the minimum value of the distance 614 may be at least the length 616 of the storage cells 602. In exemplary embodiments, the length 616 of the storage cells 602 is determined to be in the insensitive direction of the storage cell 602. In addition, an error detection mechanism 606 can be added to the array 600 in the insensitive direction. In exemplary embodiments, the storage cells 602 may include, but are not limited to, latches, CAMs, register files, flip-flops, DRAM, e-DRAM and LCBs.

In exemplary embodiments, the minimum value of the distance separating adjacent storage cells 602 can be selected to ensure that the probability of experiencing MBUs in the insensitive direction is below a desired threshold. For example, during testing of arrays 600 of storage devices 602 as the minimum value was increased from approximately the length of the storage cells 602 to approximately twice the length of the storage cells 602 the probability of experiencing an MBU in the insensitive direction of the array 600 decreased by approximately ten fold.

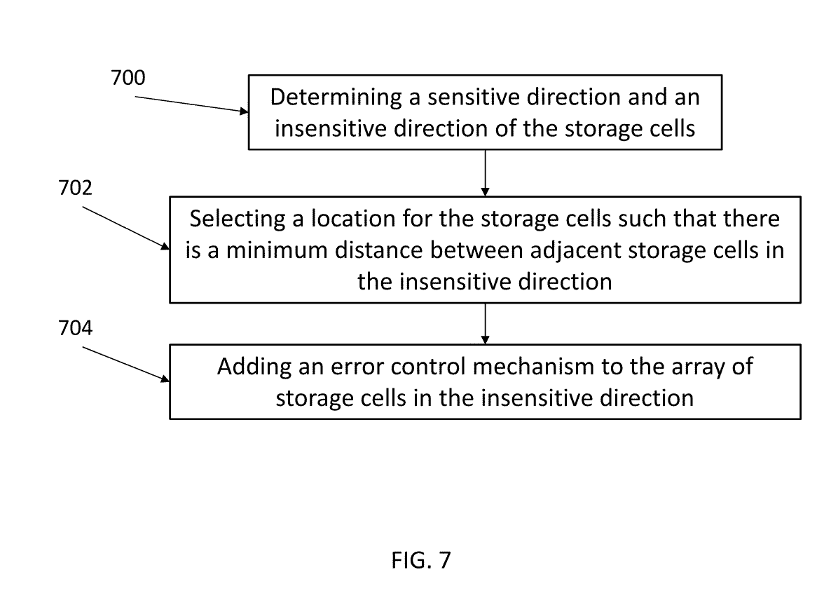

Referring now to FIG. 7, a flow diagram that illustrates a method for configuring an array of storage cells in accordance with an exemplary embodiment is shown. As shown at block 700, the method includes determining a sensitive direction and an insensitive direction of the storage cells. Next, as shown at block 702, the method includes selecting a location for the storage cells such that there is a minimum distance between adjacent storage cells in the insensitive direction. An error control mechanism is added to the array of storage cells in the insensitive direction, as shown at block 704. In exemplary embodiments, the insensitive direction is a direction perpendicular to a width of a gate conductor of the storage cells.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method for providing error detection, or error detection combined with error correction, to an array of storage cells comprising:
determining a sensitive direction and an insensitive direction of the storage cells; and
adding an error control mechanism to the array of storage cells in the insensitive direction;
wherein the insensitive direction is a direction perpendicular to a width of a gate conductor of the storage cells.

2. The method of claim 1, wherein the storage cells comprise at least one of the following: SRAM cells; latches; register file cells; content-addressable memory cells; DRAM; e-DRAM; and flip-flops.

3. The method of claim 1, wherein the error control mechanism is a parity protection bit.

4. The method of claim 1, wherein the error control mechanism is an error correction code.

5. A method for configuring an array of storage cells comprising:
determining a sensitive direction and an insensitive direction of the storage cells; and
selecting a location for the storage cells such that there is a minimum distance between adjacent storage cells in the insensitive direction;
adding an error control mechanism to the array of storage cells in the insensitive direction;
wherein the insensitive direction is a direction perpendicular to a width of a gate conductor of the storage cells.

6. The method of claim 5, wherein the storage cells comprise at least one of the following: latches; register file cells; content-addressable memory cells; DRAM; e-DRAM; and flip-flops.

7. The method of claim 5, wherein the error control mechanism is a parity protection bit.

8. The method of claim 5, wherein the error control mechanism is an error correction code.

9. The method of claim 5, wherein the minimum distance is greater than a length of the storage cells.

10. The method of claim 5, wherein the minimum distance is greater than twice a length of the storage cells.

11. A computer system for configuring an array of storage cells, the computer system comprising a processor, the computer system configured to perform a method comprising:
determining a sensitive direction and an insensitive direction of the storage cells; and
selecting a location for the storage cells such that there is a minimum distance between adjacent storage cells in the insensitive direction; and
adding an error control mechanism to the array of storage cells in the insensitive direction;
wherein the insensitive direction is a direction perpendicular to a width of a gate conductor of the storage cells.

12. The computer system of claim 11, wherein the storage cells comprise at least one of the following: latches; register file cells; content-addressable memory cells; DRAM; e-DRAM; and flip-flops.

13. The computer system of claim 11, wherein the error control mechanism is a parity protection bit.

14. The computer system of claim 11, wherein the error control mechanism is an error correction code.

15. The computer system of claim 11, wherein the minimum distance is greater than a length of the storage cells.

16. The computer system of claim 11, wherein the minimum distance is greater than twice a length of the storage cells.

17. An integrated circuit comprising:
an array of storage cells, wherein each of the storage cells includes a sensitive direction and an insensitive direction; and
an error control mechanism operable for detecting errors in the array of storage cells in the insensitive direction;
wherein the insensitive direction is a direction perpendicular to a width of a gate conductor of the storage cells.

18. The integrated circuit of claim 17, wherein the storage cells comprise at least one of the following: SRAM cells; latches; register file cells; content-addressable memory cells; DRAM; e-DRAM; and flip-flops.

19. The integrated circuit of claim 17, wherein the error control mechanism is a parity protection bit.

20. The integrated circuit of claim 17, wherein the error control mechanism is an error correction code.
